(19) United States
(12) Patent Application Publication
(10) Pub. No.: US 2008/0299500 A1
(43) Pub. Date: Dec. 4, 2008

(54) EXPOSURE APPARATUS AND DEVICE MANUFACTURING METHOD

(75) Inventor: Kenji Kawamata, Utsunomiya-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/126,713

(22) Filed: May 23, 2008

(30) Foreign Application Priority Data
May 30, 2007 (JP) 2007-144265

(51) Int. Cl. G03F 7/20; G03B 27/32

(52) U.S. Cl. 430/322; 355/27

(57) ABSTRACT

An exposure apparatus configured to expose resist which is coated on a wafer to light includes a station through which the wafer is transferred between an inside of the exposure apparatus and a coating/developing apparatus configured to coat the wafer with the resist and develop the resist coated on the wafer. The exposure apparatus further includes a controller that is configured to calculate a second time at which heat treatment is to be started in the coating/developing apparatus after the exposure of the wafer but before the development of the resist based on a first time at which the exposure of the wafer ends, and send information about the second time to the coating/developing apparatus.

### BACKGROUND OF THE INVENTION

1. Field of the Invention

The present invention relates to an exposure apparatus used for manufacturing a device such as a semiconductor device.

2. Description of the Related Art

There is a general trend toward shortening the exposure light wavelength of the exposure apparatus in order to increase resolution of the projection optical system and to achieve finer pattern exposure. According to an exposure apparatus using fluoride excimer laser or exposure light of a wavelength shorter than krypton fluoride (KrF), generally, a coater/developer (CDS) is connected in-line with the exposure apparatus. The coater/developer is used for coating a wafer with resist before exposure and developing the wafer after the exposure. The resist applied to the wafer tends to deteriorate due to ammonia or the like because of its low chemical resistance which adversely affects an imaging performance of a pattern to be exposed. Thus, the inline system which is capable of reducing time after the resist coating and keeping the wafer in a controlled environment is employed in recent exposure systems.

When a wafer which is to be exposed to light with an integrated circuit is carried to a coater/developer, the wafer is coated with resist in a resist coating unit of the coater/developer. Next, the wafer is transferred to a heating unit for high-temperature treatment (prebake) and then cooled in a cooling unit. After then, the wafer is carried to an exposure apparatus via an interface unit. The wafer which is carried to the exposure apparatus, is aligned at a prealignment unit and then mounted on a wafer stage.

On the wafer stage, the wafer is aligned with a reticle. Then, the wafer is exposed to light with the integrated circuit pattern. When the exposure is finished, the wafer is returned to the coater/developer through the interface unit. After then, the wafer is subjected to high-temperature treatment in a heating/cooling processing unit. This is post-exposure baking (PEB) which is carried out as heat processing after exposure of the wafer. After then, the wafer is cooled and developed in a developing processing unit. A wafer conveying unit which conveys the wafer among the resist coating unit, the heating/cooling processing unit and the developing processing unit in the coater/developer, moves along these units based on a time schedule which is set in advance.

An exposure system which is capable of maintaining device yield for a long period of time is discussed in Japanese Patent Application Laid-Open No. 2005-101018. According to this exposure system, a coater/developer which is used for coating a wafer with resist and developing the resist-coated wafer, and a main chamber of an exposure apparatus are connected in-line through a transfer chamber including a transfer unit therein.

As described above, if a wafer is regularly carried from the exposure apparatus into the coater/developer via the interface unit after exposure at a fixed timing, the wafer conveying unit in the coater/developer also regularly conveys the wafer to each processing unit at a fixed timing. Accordingly, the wafer processing time before the PEB processing can be fixed. Practically, however, the timing when the exposed wafer is carried into the coater/developer is not always constant. This is because the retry processing may be performed during the alignment of the reticle or the wafer, or extended time is required in exposing patterns on the wafer.

As described above, if the wafer is not carried to the coater/developer at a fixed timing, since the movement of the wafer conveying unit of the coater/developer is based on a time which is set in advance, the wafer conveying unit cannot receive the exposed wafer. Further, the wafer which was not received by the wafer conveying unit is placed on standby until the wafer conveying unit of the coater/developer comes to the wafer next time.

When the resist is a type that has low chemical resistance, if the wafer waits at the interface unit and thus the PEB processing starts later than expected, a pattern with a predetermined line width may not be obtained at the develop processing. Although the time up to start of the PEB processing can be maintained constant by setting the standby time to a maximum exposure processing time in consideration of the exposure process and the like, imaging performance or throughput may be reduced in such a case.

### SUMMARY OF THE INVENTION

The present invention is directed to a technique used for reducing a variation in a line width of a resist pattern after development processing.

[symbol]

According to an aspect of the present invention, an exposure apparatus that exposes resist which is coated on a wafer to light and includes a hand used for transferring the wafer to and from a coating/developing apparatus configured to coat the wafer with the resist and develop the resist which is coated on the wafer. The exposure apparatus includes a controller that is configured to calculate a second time at which heat treatment is started in the coating/developing apparatus after the exposure of the wafer but before the development of the resist based on a first time at which the exposure of the wafer ends, and send information about the second time to the coating/developing apparatus.

According to another aspect of the present invention, an exposure apparatus that exposes resist which is coated on a wafer to light and includes an interface unit used for transferring the wafer to and from a coating/developing apparatus configured to coat the wafer with the resist and develop the resist which is coated on the wafer. The exposure apparatus includes a heat processor configured to heat the resist which is coated on the wafer after the exposure of the wafer but before the development of the resist.

According to yet another aspect of the present invention, a device manufacturing method includes exposing a substrate, developing the exposed substrate, and processing the developed substrate for manufacturing the device using one of the aforementioned exposure apparatuses.

Further features and aspects of the present invention will become apparent from the following detailed description of exemplary embodiments with reference to the attached drawings.

### BRIEF DESCRIPTION OF THE DRAWINGS

The accompanying drawings, which are incorporated in and constitute a part of the specification, illustrate exemplary embodiments, features, and aspects of the invention and, together with the description, serve to explain the principles of the invention.

FIG. 1 illustrates an example configuration of a semiconductor manufacturing system including an exposure apparatus according to a first exemplary embodiment of the present invention.

FIG. 2 illustrates an example configuration of a semiconductor manufacturing system including an exposure apparatus according to a second exemplary embodiment of the present invention.

### DETAILED DESCRIPTION OF THE EMBODIMENTS

Various exemplary embodiments, features, and aspects of the invention will be described in detail below with reference to the drawings.

### First Exemplary Embodiment

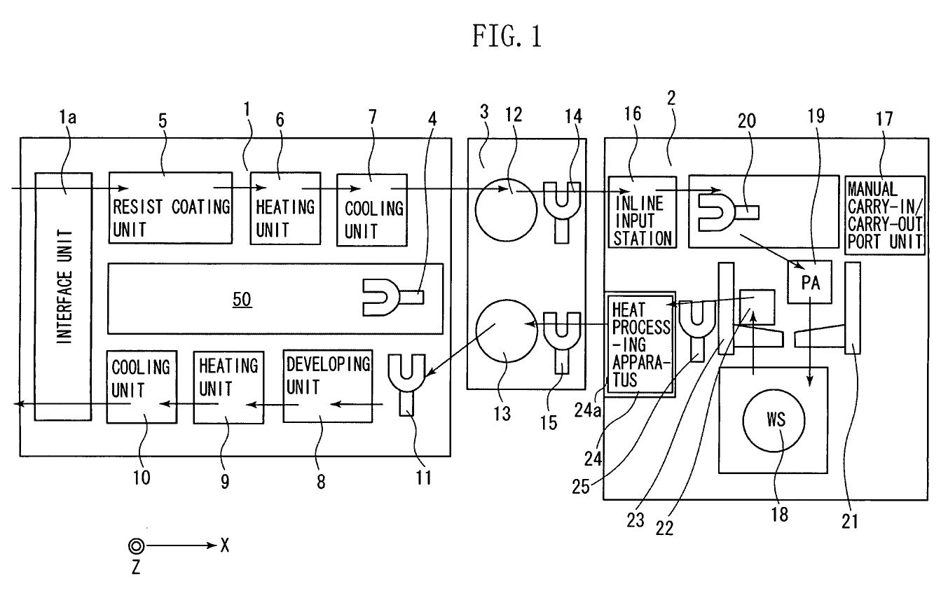

FIG. 1 illustrates an example configuration of a semiconductor manufacturing system including an exposure apparatus according to a first exemplary embodiment of the present invention. The semiconductor manufacturing system includes a coater/developer 1, an exposure apparatus 2, and an interface unit 3.

The exposure apparatus 2 receives a wafer W (not shown) from the coater/developer 1 which is a coating apparatus configured to coat the wafer W with resist, exposes the resist-coated wafer W to light, and then returns the wafer W to the coater/developer 1 which also serves as a developing apparatus of the wafer W. Further, the exposure apparatus 2 calculates a second time at which heat treatment is started at the coater/developer 1 after the exposure of the wafer W but before the development of the resist, based on a first time at which the exposure of the wafer W ends. The exposure apparatus 2 sends information about the second time to the coater/developer 1.

Further, the exposure apparatus 2 calculates the first time based on information about a shot layout. The exposure apparatus 2 calculates the first time based on information about a start time of each processing for the exposure of the wafer W. The coater/developer 1 performs processing for coating of the wafer W with resist and developing of the wafer W. The interface unit 3, which is arranged between the coater/developer 1 and the exposure apparatus 2 is configured to send the wafer W from the coater/developer 1 to the exposure apparatus 2 and return the wafer W from the exposure apparatus 2 to the coater/developer 1.

The coater/developer 1 includes an interface unit la of the coater/developer 1 and a wafer conveying hand 4. The wafer conveying hand 4 is movable along the conveyance path 50 which is formed in an X direction and also elevatable as well as rotatable. A resist coating unit 5 configured to coat the wafer W, which is carried to the coater/developer 1, with resist, a heating unit 6 configured to prebake the wafer W for better adhesion of the resist to the wafer W, and a cooling unit 7 are arranged on one side of the conveyance path 50. A developing unit 8 configured to develop the wafer W after the PEB processing, a heating unit 9 configured to heat the wafer W after the development, and a cooling unit 10 are arranged on the other side of the conveyance path 50. Further, the coater/developer 1 includes a wafer conveying hand 11 dedicated to carry the wafer W between the interface unit 3 and the developing unit 8.

The interface unit 3 includes a wafer input station 12 configured to receive the wafer W carried from the coater/developer 1 and a wafer output station 13 configured to receive the wafer W carried from the exposure apparatus 2. The interface unit 3 further includes separately a conveying hand 14 which is a first conveying unit rotatable as well as movable in a Z direction and a conveying hand 15 which is a second conveying unit. The conveying hand 14 is used for conveying the wafer W to the exposure apparatus 2 after the wafer W is coated with resist. The conveying hand 15 is used for conveying the wafer W from the exposure apparatus 2 to the wafer output station 13 after the exposure of the wafer W.

A heat processing apparatus 24 heats the wafer W after the exposure. Since inside temperature of a load lock mechanism of the heat processing apparatus 24 becomes high after the PEB processing, it is not desirable that the wafer W before the exposure is conveyed through the heat processing apparatus 24. If the temperature inside the load lock mechanism is lowered each time to a temperature that does not affect the wafer W, throughput will decline. Thus, the heat processing apparatus 24 is set at a wafer carry-out portion of the exposure apparatus 2. In this case, a wafer temperature control apparatus (not shown) is set at a wafer carry-in side of the exposure apparatus 2 to reduce uneven distribution of in-plane temperature of the wafer W before exposure.

If a heat-treated wafer is conveyed by a conveying unit, heat is transferred to the conveying unit. Thus, if a wafer W is carried from the interface unit 3 to the coater/developer 1 by a conveying unit that conveyed a heat-treated wafer, then the heat will be transferred from the conveying unit to the wafer W before the exposure, and in-plane temperature may be unevenly distributed. This leads to deformation of the wafer W and a chuck of the exposure stage and results in reduction of alignment accuracy and focus accuracy. Thus, the interface unit 3 includes two hands, the conveying hand 14 which is the first conveying unit and the conveying hand 15 which is the second conveying unit. The conveying hand 14 carries the wafer W before the exposure from the interface unit 3 to the exposure apparatus 2. The conveying hand 15 carries the wafer W after the PEB processing from the exposure apparatus 2 to the interface unit 3.

For a similar reason, a third conveying unit (conveying hand 11) which is dedicated to carrying-out the wafer W after the PEB processing from the interface unit 3 to the coater/developer 1 is provided in the coater/developer 1. In order to prevent heat from being transferred from the conveying unit dedicated to carrying-out in the interface unit 3 to the wafer W before the exposure, the first conveying unit, the second conveying unit, and the third conveying unit are arranged separately, which eliminates the need for controlling the temperature of the wafer W prior to the exposure. In this way, possibility of uneven distribution of in-plane temperature of the wafer W is reduced and time required for controlling the temperature is reduced.

Further, information about a processing state of the wafer W is shared between the exposure apparatus 2 and the coater/developer 1 via a communication unit (not shown). When the wafer W is to be carried out from the exposure apparatus 2, the third conveying unit (the conveying hand 11) of the coater/developer 1 dedicated to the carrying-out moves to a transfer position of the exposure apparatus 2. In this way, the conveying hand 11 will not fail to carry the wafer W out from the interface unit 3 and reduction of throughput can be prevented.

The exposure apparatus 2 further includes an inline input station 16 configured to receive the wafer W carried from the interface unit 3 and a manual carry-in/carry-out port 17 used for a manual mounting of a wafer carrier. Additionally, the exposure apparatus 2 includes a prealignment apparatus 19 configured to align the wafer W before the wafer W is carried to a wafer stage 18. Furthermore, the exposure apparatus 2 includes a conveying hand 20 configured to carry the wafer W from the inline input station 16 to the prealignment apparatus 19 and a wafer supplying hand 21 configured to mount the wafer W after prealignment on the wafer stage 18.

The exposure apparatus 2 further includes a wafer recovery hand 23 configured to convey the wafer W after exposure processing to a wafer recovery station 22 and a wafer recovery hand 25 configured to convey the wafer W from the wafer recovery station 22 to the heat processing apparatus 24. The inline input station 16 includes a wafer temperature control unit (not shown). The wafer temperature control unit controls temperature of the wafer W after the resist coating so that the temperature of the wafer W after the resist coating becomes equal to space temperature within the exposure apparatus 2 and thus prevents, for example, expansion of the wafer W caused by the difference in temperatures. This contributes to improving overlay accuracy.

The heat processing apparatus 24 is capable of heating/cooling the wafer W to perform the PEB processing after the exposure. Since the heat processing apparatus 24 performs the PEB processing, the heat processing apparatus 24 needs to be thermally shielded from other processing units. Thus, in consideration of the problem associated with heat generation, the heat processing apparatus 24 is enclosed in a chamber 24a having the load lock mechanism which enables transfer of the wafer W without having an influence on the exposure space. In this way, the heat processing apparatus 24 is separated from the exposure space. The heat processing apparatus 24 includes a temperature control apparatus (not shown) configured to control ambient atmosphere in the chamber 24a as well as an apparatus (not shown) used for exchanging ambient atmosphere of the chamber 24a. Further, the load lock mechanism controls ambient temperature of the heat processing apparatus 24 and exchanges ambient atmosphere as needed.

Next, referring to FIG. 1, a flow of the wafer processing in a semiconductor manufacturing system including the aforementioned exposure apparatus according to the first exemplary embodiment will be described. When the wafer W to be exposed with a pattern is carried to the coater/developer 1, the wafer W is coated with resist in the resist coating unit 5 of the coater/developer 1. After then, the wafer W is prebaked in the heating unit 6 and cooled in the cooling unit 7.

The cooled wafer W is carried to the inline input station 16 of the exposure apparatus 2 through the interface unit 3. In the inline input station 16, the wafer W is subjected to temperature control so that its in-plane temperature becomes uniform and equal to the temperature of the exposure space. Subsequently, the wafer W is carried to the prealignment apparatus 19 by the conveying hand 20. Prealignment of the wafer W is performed at the prealignment apparatus 19.

The prealigned wafer W is carried to the wafer stage 18 by the wafer supplying hand 21. After the alignment of the wafer W, the exposure of the pattern is performed. The exposure-finished wafer W is conveyed to the wafer recovery station 22 by the wafer recovery hand 23. After then, the wafer W is conveyed to the heat processing apparatus 24 by the wafer recovery hand 25.

Next, the PEB processing of the heat processing apparatus 24 will be described. The ambient temperature of the heat processing apparatus 24 within the load lock mechanism before the wafer W is carried into the heat processing apparatus, is controlled so that it becomes equal to the temperature of the exposure space. In this way, the ambient temperature of the heat processing apparatus 24 does not affect the exposure space when the load lock mechanism is opened. When the conveyance of the wafer W from the wafer recovery station 22 is started, a door of the load lock mechanism which is on the side of the exposure apparatus 2 is opened, and the wafer W is carried into the heat processing apparatus 24.

When the wafer recovery hand 25 returns to its position, the door of the load mechanism which is on the side of the exposure apparatus 2 is closed and the heating/cooling processing or the PEB processing is performed. After the PEB processing is performed, a door of the heat processing apparatus 24 on the side of the interface unit 3 is opened and the wafer W is carried to the wafer output station 13 by the conveying hand 15 of the interface unit 3. The wafer W which is carried out from the exposure apparatus 2 to the interface unit 3 is conveyed to the developing unit 8 by the conveying hand 11 which is the third conveying unit of the coater/developer 1. After the wafer W is developed in the developing unit 8, the wafer W is processed in the heating unit 9 and the cooling unit 10 and then carried out from the coater/developer 1.

As described above, by arranging the heat processing apparatus 24 in the exposure apparatus 2 of the first exemplary embodiment and performing the PEB processing in the exposure apparatus 2, time from the end of the exposure to the PEB processing can be kept constant. Further, by providing the conveying hand 11, which is dedicated to transferring the wafer between the interface unit 3 and the coater/developer 1, the wafer will no longer need to wait in a standby state on the wafer output station 13 of the interface unit 3 or in the heat processing apparatus 24 of the exposure apparatus 2, and the whole processing time can be reduced to a minimum. As a result, decrease in pattern imaging performance after development processing and variation on pattern line width can be prevented.

### Second Exemplary Embodiment

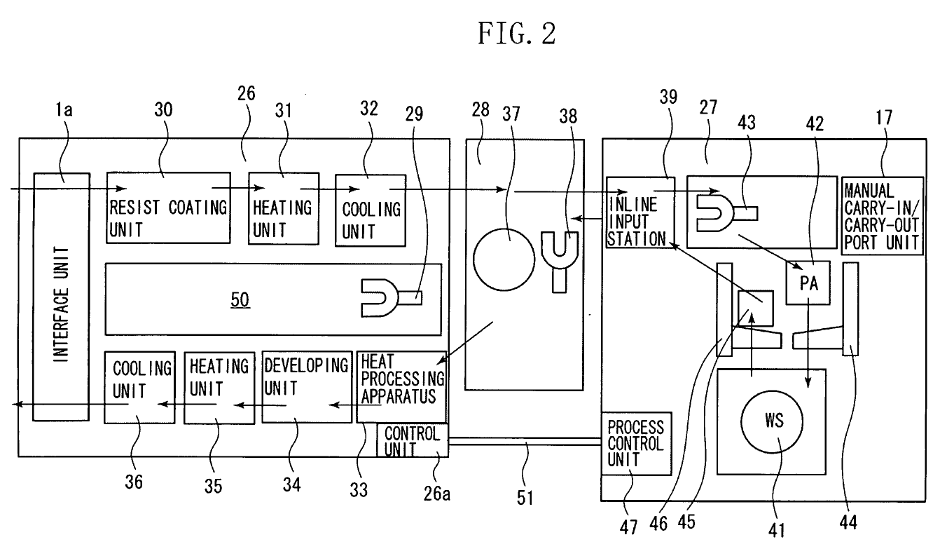

Next, referring to FIG. 2, a semiconductor manufacturing system including an exposure apparatus according to a second exemplary embodiment of the present invention will be described. The semiconductor manufacturing system including an exposure apparatus according to the second exemplary embodiment has a configuration similar to that of the semiconductor manufacturing system according to the first exemplary embodiment illustrated in FIG. 1. However, the conveying hand 11 that is the third conveying unit of the first exemplary embodiment is omitted from a coater/developer 26, which is a coating apparatus configured to coat the wafer W with resist and develop the resist-coated wafer W. Further, a heat processing apparatus 33 is added to the coater/developer 26. An interface unit 28, which is arranged between the coater/developer 26 and the exposure apparatus 27, includes a wafer station 37 and a conveying hand 38. The wafer W is carried to the exposure apparatus 2 from the wafer station 37 and carried back to the wafer station 37 from the exposure apparatus. The conveying hand 38 is used for transferring the wafer W to and from the exposure apparatus 27.

The exposure apparatus 27 exposes the resist which is coated on the wafer W to light. The heat processing apparatus 33 performs heat processing of the resist which is coated on the wafer W after the exposure but before the development of the resist. Further, the heat processing apparatus 33 cools the resist coated on the wafer W after the heat processing. The heat processing apparatus 33 includes a load lock mechanism. Further, the exposure apparatus 27 includes a conveying hand 43 used for carrying the wafer W before its exposure.

The coater/developer 26 includes a conveying hand 29 used for conveying the wafer W which is heat-treated by the heat processing apparatus 33. The heat processing apparatus 24 and the wafer recovery hand 25 which is included in the exposure apparatus 2 according to the first exemplary embodiment are omitted from the exposure apparatus 27 of the present exemplary embodiment. The exposure apparatus 27 includes a process control unit 47 which collects information about a processing state of the wafer W in each processing unit, calculates a time at which the exposure processing ends, issues an order to the coater/developer 26 so that time from the end of the exposure to the PEB processing remains constant and can be reduced to the minimum. Further, a communication unit 51 which is used when the coater/developer 26 and the exposure apparatus 27 exchange various types of information, such as a processing state of the wafer W, is provided between the apparatuses.

Next, referring to FIG. 2, a flow of the wafer W in a semiconductor manufacturing system including the aforementioned exposure apparatus according to the second exemplary embodiment will be described. When the wafer W which is exposed with a pattern is carried to the coater/developer 26, the wafer W is coated with resist in the resist coating unit 30 of the coater/developer 26. After then, the wafer W is prebaked in the heating unit 31 and cooled in the cooling unit 32.

The cooled wafer W is carried from the interface unit 28 to the exposure apparatus 27 through the IN side of the inline station 39. The process control unit 47 of the exposure apparatus 27 calculates timing that the wafer W is carried out from the exposure apparatus 27 after the exposure of the wafer W is performed based on information such as layout information. The calculation result will be carry-out timing when subsequent exposure processing is performed without delay, which is also a default value of the carry-out timing. Based on the carry-out timing, the process control unit 47 calculates the start time of the PEB processing and notifies a control unit 26a in the coater/developer 26 of the result through the communication unit 51. At the inline station 39, the wafer W is conditioned so that its in-plane temperature becomes equal to the temperature of the exposure space.

Subsequently, the wafer W is carried to the prealignment apparatus 42 by the conveying hand 43. Prealignment of the wafer W is performed at the prealignment apparatus 42. The prealigned wafer W is mounted on a wafer stage 41 by a wafer supplying hand 44. After the wafer W is aligned, the wafer W is exposed to light with a desired pattern. The exposure-finished wafer W is conveyed to a wafer recovery station 45 by a wafer recovery hand 46. After then, the wafer W is conveyed to the OUT side of the inline station 39 by the conveying hand 43.

If retry of the wafer W occurs by the end of the exposure processing, the PEB processing may not be started at a timing which the coater/developer 26 is notified of. In such a case, when the retry processing is performed, each processing unit of the exposure apparatus 27 notifies the process control unit 47 that the PEB processing may not be started at the expected timing. Based on the notification, the process control unit 47 recalculates the start time of the PEB processing and notifies the coater/developer 26 of the recalculated time. The process control unit 47 repeats recalculations of the start time of the PEB processing and notifications to the coater/developer 26, so that the exposure apparatus 27 can manage optimum start time of the PEB processing.

In the aforementioned processing, the wafer W is the first wafer. Now, a case where the wafer W is a second or a later wafer be described. When a first wafer is carried to the prealignment apparatus 42 by the conveying hand 43, the wafer conveying hand 43 moves back to the inline station 39, receives a second wafer from the IN side of the inline station 39, and moves again to the prealignment apparatus 42.

At this time, since the second wafer can reach the prealignment apparatus 42 before the prealignment of the first wafer is finished, the second wafer waits for Δt1 seconds before it is carried to the prealignment apparatus 42. Subsequently, the first wafer is carried to the wafer stage 41 and the prealignment of the second wafer is started. Once again, the prealignment of the second wafer is finished earlier than the exposure processing of the first wafer. Thus, the second wafer waits for Δt2 seconds on the wafer supplying hand 44.

When the exposure processing of the first wafer is finished and the wafer is removed from the wafer stage 41 by the wafer recovery hand 46, the second wafer is mounted on the wafer stage 41 and its exposure is started. Accordingly, the end of the exposure of the second wafer will be delayed for (Δt1+Δt2) seconds from the default value. Further, if a retry of the exposure processing of the first wafer is performed, then the second wafer needs to wait for a longer time for (Δt1′+Δt2′) second. If a retry of any of the processing of the second wafer is performed, the end of the exposure of the second wafer will be further delayed for (Δt1′+Δt2′+Δt3) seconds.

In consideration of this delay, the process control unit 47 of the exposure apparatus 27 recalculates the start timing of the PEB processing and notifies the control unit 26a in the coater/developer 26 of the result. Similarly, regarding an N-th wafer which is a third or a later wafer, the process control unit 47 updates a start timing of the PEB processing as needed based on a sum ΔT1 of the wait time in each processing unit and a delay ΔT2 according to the retry processing of N-th wafer.

The process control unit 47 obtains the standby time of the wafer in each processing unit by managing a start time of each processing. If retry processing is performed in a processing unit, information that a delay has occurred is sent from the processing unit to the process control unit 47 through the communication unit 51. The process control unit 47, which keeps data on delayed processing, refers to the data and calculates the delay at the processing unit. The wafer W which is carried out from the exposure apparatus 27 to the interface unit 28 is conveyed to the heat processing apparatus 33 by the conveying hand 29 of the coater/developer 26. In the heat processing apparatus 33, heat is applied to the wafer W as the PEB processing and then wafer W is cooled. The conveying hand 29 of the coater/developer 26 receives the wafer W from the interface unit 28 at a timing based on the starting time of the PEB processing which is notified by the exposure apparatus 27 to the control unit 26a. Then the conveying hand 29 conveys the wafer W to the heat processing apparatus 33.

The semiconductor manufacturing system including the exposure apparatus according to the second exemplary embodiment illustrated in FIG. 2 includes a single conveying hand in the coater/developer 26. However, a conveying hand (not shown) as a third conveying unit which is dedicated to conveying the wafer W from the interface unit 28 to the heat processing apparatus 33 may also be provided. In this case, processing other than the PEB processing such as the develop processing can be performed in parallel. This contributes to preventing reduction of throughput of the coater/developer 26. After the PEB processing, the wafer W is developed at a developing unit 34. After the wafer W is processed in a heating unit 35 and a cooling unit 36, the wafer is carried out from the coater/developer 26.

As described above, since the exposure apparatus 27 manages the start time of the PEB processing, time from the end of the exposure to the PEB processing can be minimized and held constant. Thus, decrease in pattern imaging performance after development processing and variation of pattern line width can be prevented. However, since the end of the exposure time depends on retry processing such as alignment during the exposure processing, the start time of the PEB processing needs to be recalculated and notified if retry processing is performed.

Next, an exemplary embodiment of a device manufacturing method using the above-described exposure apparatus will be described. A device such as a semiconductor integrated circuit element or a liquid crystal display element is manufactured using the exposure apparatus according to one of the aforementioned exemplary embodiments through an exposure process of a substrate such as a wafer or a glass plate that is coated with a photosensitive material, a development process of the exposure-finished substrate, and other known processes.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures, and functions.

This application claims priority from Japanese Patent Application No. 2007-144265 filed May 30, 2007, which is hereby incorporated by reference herein in its entirety.

What is claimed is:

1. An exposure apparatus that exposes resist coated on a wafer to light and includes a station through which the wafer is transferred between an inside of the exposure apparatus and a coating/developing apparatus configured to coat the wafer with the resist and develop the resist coated on the wafer, the exposure apparatus comprising:
a controller configured to calculate a second time at which heat treatment is to be started in the coating/developing apparatus after the exposure of the wafer but before the development of the resist based on a first time at which the exposure of the wafer ends, and send information about the second time to the coating/developing apparatus.

2. An apparatus according to claim 1, wherein the controller is configured to calculate the first time based on information of a shot layout for the wafer.

3. An apparatus according to claim 1, wherein the controller is configured to calculate the first time based on information of start time of each processing for exposure of the wafer.

4. An exposure apparatus that exposes resist coated on a wafer to light and includes a station through which the wafer is transferred between an inside of the exposure apparatus and a coating/developing apparatus configured to coat the wafer with the resist and develop the resist coated on the wafer, the exposure apparatus comprising:
a heat processor configured to heat the resist coated on the wafer after the exposure of the wafer but before the development of the resist.

5. An apparatus according to claim 4, wherein the heat processor is configured to heat and then cool the resist coated on the wafer.

6. An apparatus according to claim 4, wherein the heat processor includes a load lock mechanism.

7. An apparatus according to claim 4, further comprising an interface unit that includes a first hand configured to carry in the wafer before exposure and a second hand configured to carry out the wafer which is heated by the heat processor.

8. A method of manufacturing a device utilizing an exposure apparatus that exposes resist coated on a wafer to light and includes a station through which the wafer is transferred between an inside of the exposure apparatus and a coating/developing apparatus configured to coat the wafer with the resist and develop the resist coated on the wafer, the apparatus including a controller configured to calculate a second time at which heat treatment is to be started in the coating/developing apparatus after the exposure of the wafer but before the development of the resist based on a first time at which the exposure of the wafer ends, and send information about the second time to the coating/developing apparatus, the method comprising:
exposing a substrate to light using the exposure apparatus;
developing the exposed substrate; and
processing the developed substrate to manufacture the device.

9. A method of manufacturing a device an exposure apparatus that exposes resist coated on a wafer to light and includes a station through which the wafer is transferred between an inside of the exposure apparatus and a coating/developing apparatus configured to coat the wafer with the resist and develop the resist coated on the wafer, the apparatus including a heat processor configured to heat the resist coated on the wafer after the exposure of the wafer but before the development of the resist, the method comprising:
exposing a substrate to light using the exposure apparatus;
developing the exposed substrate; and
processing the developed substrate to manufacture the device.
